(19) United States
(12) Patent Application Publication
(10) Pub. No.: US 2020/0135668 A1
(43) Pub. Date: Apr. 30, 2020

(54) SEMICONDUCTOR DEVICE

(71) Applicant: Fuji Electric Co., Ltd., Kanagawa (JP)

(72) Inventor: Yoshinori IWASAKI, Nagano (JP)

(73) Assignee: Fuji Electric Co., Ltd., Kanagawa (JP)

(21) Appl. No.: 16/577,963

(22) Filed: Sep. 20, 2019

(30) Foreign Application Priority Data
Oct. 24, 2018 (JP) 2018-200287

(51) Int. Cl. H01L 23/64; H01L 25/07; H01L 25/18; H01L 23/31; H01L 23/498; H01L 49/02

(52) U.S. Cl. CPC H01L 23/642; H01L 25/072; H01L 25/18; H01L 28/40; H01L 23/49844; H01L 28/20; H01L 23/3121

(57) ABSTRACT

This semiconductor device includes: a circuit substrate; a printed substrate disposed so as to face the circuit substrate; switching elements attached to the circuit substrate; a circuit impedance reduction element attached to the printed substrate; a first conductive post; a second conductive post; a first external connection terminal; and a second external connection terminal. The switching elements collectively have a first electrode and a second electrode. The circuit impedance reduction element includes a third electrode and a fourth electrode. A length of a current path between the first external connection terminal and the third electrode is shorter than a length of a current path between the first external connection terminal and the first electrode. A length of a current path between the second external connection terminal and the fourth electrode is shorter than a length of a current path between the second external connection terminal and the second electrode.

### BACKGROUND OF THE INVENTION

### Technical Field

The present invention relates to a semiconductor device.

### Background Art

In an inverter device, uninterruptible power supply device, machine tool, industrial robot, etc., a semiconductor device (hereinafter also referred to as a power semiconductor module) on which power semiconductor elements are mounted is used separately from the main body device (see Patent Documents 1 and 2, for example).

### RELATED ART DOCUMENTS

### Patent Documents

Patent Document 1: WO 2014/185050

Patent Document 2: Japanese Patent Application Laid-Open Publication No. 2013-222950

### SUMMARY OF THE INVENTION

In the power semiconductor module disclosed in Patent Document 1, oscillation of the gate electrode voltage of a semiconductor chip is suppressed, but there are no oscillation suppressing effects for the source-drain voltage. In particular, a power semiconductor module (hereinafter also referred to as a SiC module) on which is mounted an SiC (silicon carbide)-MOSFET (metal oxide semiconductor field-effect transistor) as the power semiconductor element has faster switching than an IGBT (insulated gate bipolar transistor), and thus the drain-source surge voltage tends to be large. Due to this, in a SiC module, it is desirable to reduce the surge voltage of the drain-source (namely, in the current path of the switching element) and to suppress oscillation of voltage.

The present invention was made with attention to the aforementioned problems and aims at providing a semiconductor device with which it is possible to reduce surge voltage in the current path of the switching element and to suppress oscillation of voltage.

Additional or separate features and advantages of the invention will be set forth in the descriptions that follow and in part will be apparent from the description, or may be learned by practice of the invention. The objectives and other advantages of the invention will be realized and attained by the structure particularly pointed out in the written description and claims thereof as well as the appended drawings.

To achieve these and other advantages and in accordance with the purpose of the present invention, as embodied and broadly described, in one aspect, the present disclosure provides a semiconductor device, comprising: a circuit substrate; a printed substrate disposed above the circuit substrate so as to face the circuit substrate; switching elements attached to the circuit substrate, collectively having a first electrode as a positive-side electrode and a second electrode as a negative-side electrode; a circuit impedance reduction element attached to the printed substrate; a first conductive post electrically and mechanically connected to the circuit substrate and the printed substrate; a second conductive post disposed in a position separated from the first conductive post and electrically and mechanically connected to the circuit substrate and the printed substrate; a first external connection terminal going through the printed substrate and mechanically connected to the circuit substrate, and electrically connected to the first electrode; and a second external connection terminal going through the printed substrate and mechanically connected to the circuit substrate, and electrically connected to the second electrode, wherein the circuit impedance reduction element includes: a third electrode electrically connected to the first external connection terminal via the first conductive post; and a fourth electrode electrically connected to the second external connection terminal via the second conductive post, wherein a length of a current path between the first external connection terminal and the third electrode is shorter than a length of a current path between the first external connection terminal and the first electrode, and wherein a length of a current path between the second external connection terminal and the fourth electrode is shorter than a length of a current path between the second external connection terminal and the second electrode.

The present invention makes it possible to provide a semiconductor device with which it is possible to reduce surge voltage in the current path of the switching element and to suppress oscillation of voltage.

It is to be understood that both the foregoing general description and the following detailed description are exemplary and explanatory, and are intended to provide further explanation of the invention as claimed.

### BRIEF DESCRIPTION OF THE DRAWINGS

FIG. 1 is a plan view of a configuration example of a semiconductor device according to Embodiment 1 of the present invention.

FIG. 2 is a plan view of a configuration example of the semiconductor device according to Embodiment 1 of the present invention.

FIG. 3 is a plan view of a configuration example of the semiconductor device according to Embodiment 1 of the present invention.

FIG. 4 is a cross-sectional view of a configuration example of the semiconductor device according to Embodiment 1 of the present invention.

FIG. 5 is a cross-sectional view of a configuration example of the semiconductor device according to Embodiment 1 of the present invention.

FIG. 6 is a cross-sectional view of a configuration example of the semiconductor device according to Embodiment 1 of the present invention.

FIG. 7 is a circuit diagram of an equivalent circuit of the semiconductor device according to Embodiment 1 of the present invention.

FIG. 8 is a view of current paths of the semiconductor device according to Embodiment 1 of the present invention.

FIG. 9 is a plan view of a configuration example of a semiconductor device according to Embodiment 2 of the present invention.

FIG. 10 is a cross-sectional view of a configuration example of the semiconductor device according to Embodiment 2 of the present invention.

FIG. 11 is a circuit diagram of an equivalent circuit of the semiconductor device according to Embodiment 2 of the present invention.

FIG. 12 is a view of current paths of the semiconductor device according to Embodiment 2 of the present invention.

FIG. 13 is a cross-sectional view of a configuration example of a printed substrate according to Embodiment 3 of the present invention.

FIG. 14 is a cross-sectional view of a configuration example of the printed substrate according to Embodiment 3 of the present invention.

### DETAILED DESCRIPTION OF EMBODIMENTS

Embodiments of the present invention will be described below. In the drawings, parts that are the same or similar will be assigned the same or similar reference characters. However, it should be noted that the drawings are schematic, and that the relationship between thickness and the planar dimensions and the proportions or the like among the thicknesses of each device and each member differ in practice. Thus, specific thicknesses and dimensions should be determined in reference to the description below. Furthermore, it goes without saying that there are parts that differ in the dimensional relationships and proportions thereof even among the drawings. In particular, in the disclosed semiconductor devices, the dimensions in the thickness direction (the Z-axis direction below) are actually significantly smaller than the dimensions in the planar directions (the X-axis direction and Y-axis directions below). Because of this, in the drawings, the dimensions in the Z-axis direction are expanded relative to the X-axis and Y-axis directions for ease of illustration.

In the descriptions regarding the drawings below, there are cases where directions are indicated by using the X-axis direction, Y-axis direction, and Z-axis direction. For example, the X-axis direction and the Y-axis direction are directions parallel to a front surface 10a of an insulating circuit substrate 10, which is described later. The Z-axis direction is the thickness direction of the insulating circuit substrate 10, which is described later. The Z-axis direction is orthogonal to the X-axis direction, and the Y-axis direction and the Z-axis direction are orthogonal to each other.

Furthermore, in the description below, there are cases where the Z-axis positive direction is referred to as “up” and the Z-axis negative direction is referred to as “down.” “Up” and “down” do not necessarily signify a vertical direction with respect to the ground. In other words, the directions of “up” and “down” are not limited to the gravitational direction. “Up” and “down” are merely expressions of convenience for specifying the relative positional relationship in a layer, substrate, etc., and do not limit the technical idea of the present invention. If the sheet of paper were turned 180 degrees, for example, then it goes without saying that “up” would become “down” and “down” would become “up.”

The term “electrically and mechanically connected” in the description below is not limited to situations in which the target objects are connected to each other by direct bonding, but rather includes situations in which the target objects are connected via a conductive bonding material such as solder or a metallic sintering material. Furthermore, “the same” not only signifies completely the same, but also includes approximately the same or practically the same. In addition, “plan view” means seen from a direction normal to the front surface 10a (in other words, from the Z-axis direction).

### Embodiment 1

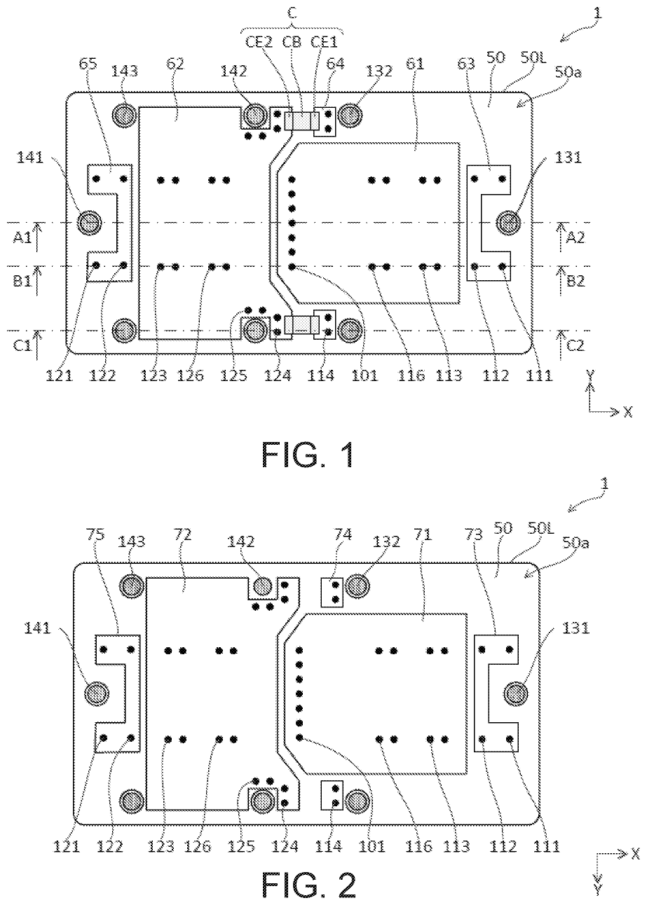

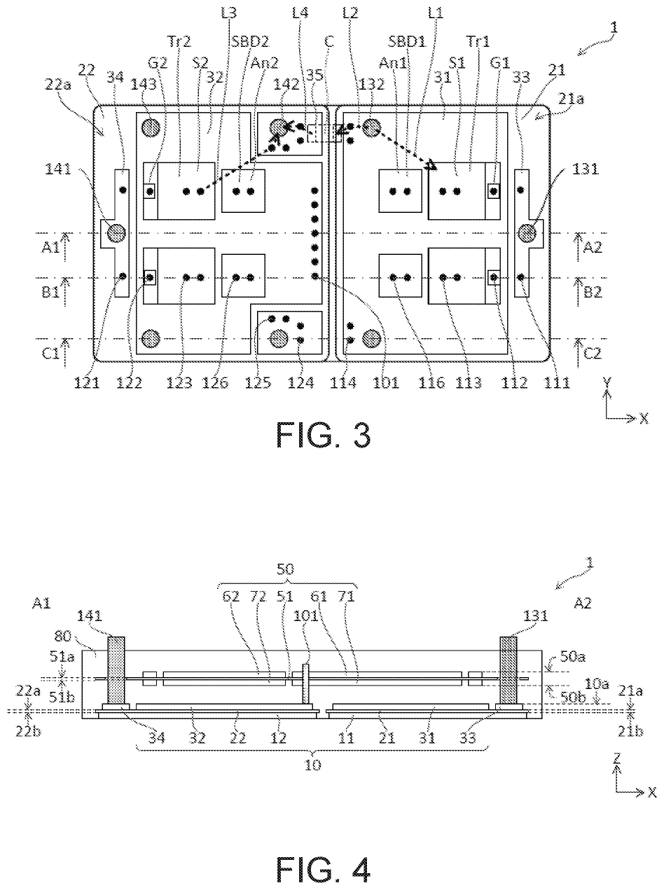

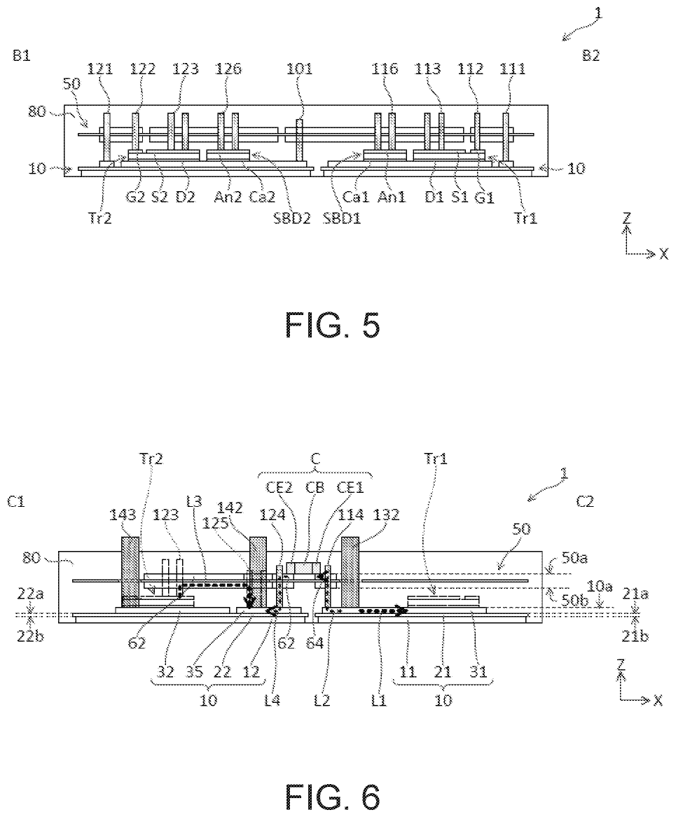

FIGS. 1 to 3 are plan views of configuration examples of a semiconductor device according to Embodiment 1 of the present invention. FIGS. 4 to 6 are cross-sectional views of configuration examples of the semiconductor device according to Embodiment 1 of the present invention. Specifically, FIG. 1 is a plan view of a configuration example of a front surface 50a side of a printed substrate 50 of a semiconductor device 1 according to Embodiment 1. FIG. 2 is a plan view of a configuration example of a rear surface 50b side of the printed substrate 50. FIG. 3 is a plan view of a configuration example of an insulating circuit substrate 10 of the semiconductor device 1. FIG. 4 is a cross-sectional view in which the semiconductor device 1 has been cut along the A1-A2 line shown in FIG. 1 and FIG. 3. FIG. 5 is a cross-sectional view in which the semiconductor device 1 has been cut along the B1-B2 line shown in FIG. 1 and FIG. 3. FIG. 6 is a cross-sectional view in which the semiconductor device 1 has been cut along the C1-C2 line shown in FIG. 1 and FIG. 3.

The semiconductor device shown in FIGS. 1 to 6 is a power semiconductor module on which are mounted power semiconductor elements, and is a 2-in-1 module (the upper and lower arms are packaged in one package). The semiconductor device 1 includes: the insulating circuit substrate 10; a first semiconductor chip Tr1, which is a power semiconductor element; a second semiconductor chip Tr2, which is a power semiconductor element; the printed substrate 50; conductive posts 101, 111 to 114, 116, 121 to 126; external connection terminals 131, 132, 141 to 143; a capacitor C; a first reflux diode SBD1; a second reflux diode SBD2; and an insulating resin 80. The power semiconductor elements are SiC-MOSFETs, for example. Furthermore, the external connection terminal 132 is used as a positive potential-side external connection terminal (P terminal). The external connection terminal 142 is used as a negative potential-side external connection terminal (N terminal). The external connection terminal 143 is used as an output terminal (O terminal).

The insulating circuit substrate 10 includes: insulating plates 21, 22; circuit plates 31, 33 fixed to a front surface 21a of the insulating plate 21; circuit plates 32, 34, 35 fixed to a front surface 22a of the insulating plate 22; and metal plates 11, 12 fixed to rear surfaces 21b, 22b of the insulating plates 21, 22, respectively. The insulating plates 21, 22 are made of an insulating member such as ceramic. The circuits 31 to 35 and the metal plates 11 and 12 are made of copper, aluminum, etc. The insulating plates 21, 22 are disposed so as to be separated from each other. The metal plates 11, 12 are disposed so as to be separated from each other. In addition, on the insulating plate 21, the circuit plates 31, 33 are disposed so as to be separated from each other. On the insulating plate 22, the circuit plates 32, 34, and 35 are disposed so as to be separated from each other.

The printed substrate 50 is disposed at a position facing the front surface 10a of the insulating circuit substrate 10 (the surface on the side where the circuit plates 31 to 35 are fixed). The printed substrate 50 includes: an insulating base member 51; conductive layers 61 to 65 disposed on a front surface 51a side of the base member 51; and conductive layers 71 to 75 disposed on a rear surface 51b side of the base member 51. The conductive layers 61 to 65, 71 to 75 are made of a metal such as copper. The conductive layers 61, 71 have the same shape and the same size, for example. In a plan view seeing through the base member 51, the conductive layers 61, 71 are disposed in positions overlapping each other. The conductive layers 61, 71 are electrically connected to each other through the conductive posts 101, 113, 116 inserted into through-holes in the printed substrate 50.

Similarly, the conductive layers 62, 72 have the same shape and the same size, for example. In a plan view seeing through the base member 51, the conductive layers 62, 72 are disposed in positions overlapping each other. The conductive layers 62, 72 are electrically connected to each other through the conductive posts 123 to 126 inserted into through-holes in the printed substrate 50.

The conductive layers 63, 73 have the same shape and the same size, for example. In a plan view seeing through the base member 51, the conductive layers 63, 73 are disposed in positions overlapping each other. The conductive layers 63, 73 are electrically connected to each other through the conductive posts 111, 112 inserted into through-holes in the printed substrate 50.

The conductive layers 65, 75 have the same shape and the same size, for example. In a plan view seeing through the base member 51, the conductive layers 65, 75 are disposed in positions overlapping each other. The conductive layers 65, 75 are electrically connected to each other through the conductive posts 121, 122 inserted into through-holes in the printed substrate 50.

The first semiconductor chip Tr1 is a SiC-MOSFET in which SiC, which is a wide-bandgap semiconductor, is used. The first semiconductor chip Tr1 has a gate electrode G1 and a source electrode S1 on the front surface, and a drain electrode D1 on the rear surface. The drain electrode D1 of the first semiconductor chip Tr1 is electrically and mechanically connected via a conductive bonding material to the circuit plate 31. Furthermore, the conductive post 113 is disposed on the source electrode S1. The conductive post 113 is electrically and mechanically connected via a conductive bonding material to the source electrode S1 and the conductive layers 61, 71 of the printed substrate 50. The conductive post 112 is disposed on the gate electrode G1. The conductive post 112 is electrically and mechanically connected via a conductive bonding material to the gate electrode G1 and the conductive layers 63, 73 of the printed substrate 50. The first semiconductor chip Tr1 turns ON and OFF current flowing between the drain electrode D1 and the source electrode S1 on the basis of a voltage signal applied to the gate electrode G1. The first semiconductor chip Tr1 is used as a switching element.

Similarly, the second semiconductor chip Tr2 is a SiC-MOSFET in which SiC, which is a wide-bandgap semiconductor, is used. The second semiconductor chip Tr2 has a gate electrode G2 and a source electrode S2 on the front surface, and a drain electrode D2 on the rear surface. The drain electrode D2 of the second semiconductor chip Tr2 is electrically and mechanically connected via a conductive bonding material to the circuit plate 32. Furthermore, the conductive post 123 is disposed on the source electrode S2. The conductive post 123 is electrically and mechanically connected via a conductive bonding material to the source electrode S2 and the conductive layers 62, 72 of the printed substrate 50. The conductive post 122 is disposed on the gate electrode G2. The conductive post 122 is electrically and mechanically connected via a conductive bonding material to the gate electrode G2 and the conductive layers 65, 75 of the printed substrate 50. The second semiconductor chip Tr2 turns ON and OFF current flowing between the drain electrode D2 and the source electrode S2 on the basis of a voltage signal applied to the gate electrode G2. The second semiconductor chip Tr2 is used as a switching element.

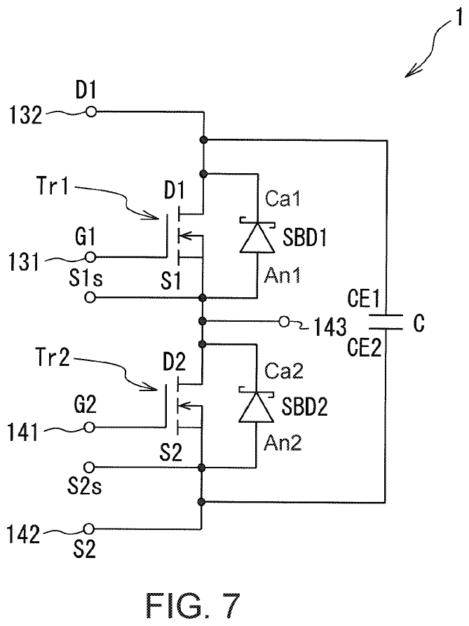

The first reflux diode SBD1 is a Zener diode. The first reflux diode SBD1 has an anode electrode An1 (see FIG. 7, which is described later) on the front surface, and a cathode electrode Ca1 (refer to FIG. 7, which is described later) on the rear surface. The cathode electrode Ca1 of the first reflux diode SBD1 is electrically and mechanically connected via a conductive bonding material to the circuit plate 31. The conductive post 116 is disposed on the anode electrode An1 of the first reflux diode SBD1. The conductive post 116 is electrically and mechanically connected via a conductive bonding material to the anode electrode An1 of the first reflux diode SBD1 and the conductive layers 61, 71 of the printed substrate 50. This connects the first reflux diode SBD1 in parallel to the first semiconductor chip Tr1.

Similarly, the second reflux diode SBD2 is a Zener diode. The second reflux diode SBD2 has an anode electrode An2 (see FIG. 7, which is described later) on the front surface, and a cathode electrode Ca2 (refer to FIG. 7, which is described later) on the rear surface. The cathode electrode Ca2 of the second reflux diode SBD2 is electrically and mechanically connected via a conductive bonding material to the circuit plate 32. The conductive post 126 is disposed on the anode electrode An2 of the second reflux diode SBD2. The conductive post 126 is electrically and mechanically connected via a conductive bonding material to the anode electrode An2 of the second reflux diode SBD2 and the conductive layers 62, 72 of the printed substrate 50. This connects the second reflux diode SBD2 in parallel to the second semiconductor chip Tr2, as shown in FIG. 7, which is described later.

The conductive post 114 and the external connection terminal 132 are disposed on the circuit plate 31. The conductive post 114 is electrically and mechanically connected via a conductive bonding material to the circuit plate 31 and the conductive layer 64 of the printed substrate 50. Furthermore, the external connection terminal 132 is electrically and mechanically connected via a conductive bonding material to the circuit plate 31. The external connection terminal 132 is inserted into a through-hole provided in the printed substrate 50 and mechanically connected to the printed substrate 50, but not electrically connected to the printed substrate 50.

The conductive post 101 and the external connection terminal 143 are disposed on the circuit plate 32. The conductive post 101 is electrically and mechanically connected via a conductive bonding material to the circuit plate 32 and the conductive layers 61, 71 of the printed substrate 50. Furthermore, the external connection terminal 143 is electrically and mechanically connected via a conductive bonding material to the circuit plate 32. The external connection terminal 143 is inserted into a through-hole provided in the printed substrate 50 and mechanically connected to the printed substrate 50, but not electrically connected to the printed substrate 50.

The conductive post 111 and the external connection terminal 131 are disposed on the circuit plate 33. The conductive post 111 is electrically and mechanically connected via a conductive bonding material to the circuit plate 33 and the conductive layers 63, 73 of the printed substrate 50. Furthermore, the external connection terminal 131 is electrically and mechanically connected via a conductive bonding material to the circuit plate 33. The external connection terminal 131 is inserted into a through-hole provided in the printed substrate 50 and mechanically connected to the printed substrate 50, but not electrically connected to the printed substrate 50.

The conductive post 121 and the external connection terminal 141 are disposed on the circuit plate 34. The conductive post 121 is electrically and mechanically connected via a conductive bonding material to the circuit plate 34 and the conductive layers 65, 75 of the printed substrate 50. In addition, the external connection terminal 141 is electrically and mechanically connected via a conductive bonding material to the circuit plate 34. The external connection terminal 141 is inserted into a through-hole provided in the printed substrate 50 and mechanically connected to the printed substrate 50, but not electrically connected to the printed substrate 50.

The conductive posts 124, 125 and the external connection terminal 142 are disposed on the circuit plate 35. The conductive posts 124, 125 are electrically and mechanically connected via a conductive bonding material to the circuit plate 35 and the conductive layers 62, 72 of the printed substrate 50. Furthermore, the external connection terminal 142 is electrically and mechanically connected via a conductive bonding material to the circuit plate 35. The external connection terminal 142 is inserted into a through-hole provided in the printed substrate 50 and mechanically connected to the printed substrate 50, but not electrically connected to the printed substrate 50.

A capacitor C is attached to the printed substrate 50. The capacitor C is a ceramic capacitor, for example, and includes a ceramic capacitor body CB and electrodes CE1, CE2 positioned on both ends of the body. The electrode CE1 is electrically and mechanically connected via a conductive bonding material to the conductive layer 64. The electrode CE2 is electrically and mechanically connected via a conductive bonding material to the conductive layer 62.

As shown in FIG. 1 and FIG. 6, in the printed substrate 50, two of the conductive posts 114 are disposed between the capacitor C and the external connection terminal 132. In the printed substrate 50, two of the conductive posts 124 are also disposed between the capacitor C and the external connection terminal 142.

The insulating resin 80 covers and seals the front surface 10a side of the insulating circuit substrate 10, the first semiconductor chip Tr1, the second semiconductor chip Tr2, the printed substrate 50, the capacitor C, and the conductive posts 101, 111 to 114, 116, 121 to 126. The external connection terminals 131, 132, 141 to 143 protrude from the insulating resin 80. Furthermore, the metal plates 11 and 12 of the insulating circuit substrate 10 are exposed from the insulating resin 80. The insulating resin 80 is made of an epoxy resin, which is a thermosetting resin, for example.

FIG. 7 is a circuit diagram of an equivalent circuit of the semiconductor device according to Embodiment 1 of the present invention. As shown in FIG. 7, in the semiconductor device 1, the first semiconductor chip Tr1 and the second semiconductor chip Tr2 are connected to each other in series. In other words, the source electrode S1 of the first semiconductor chip Tr1 and the drain electrode D2 of the second semiconductor chip Tr2 are connected to each other in series. Furthermore, the capacitor C is connected in parallel to the first semiconductor chip Tr1 and the second semiconductor chip Tr2 that are connected to each other in series.

In FIG. 7, one capacitor C is shown, but there is not a limit on the number of capacitors C in the embodiments of the present invention. As shown in FIG. 1, for example, the semiconductor device 1 may have two capacitors C, and the two capacitors may be connected to each other in parallel.

As shown in FIG. 7, the drain electrode D1 of the first semiconductor chip Tr1, the cathode electrode Ca1 of the first reflux diode SBD1, and the electrode CE1 of the capacitor C are electrically connected to the external connection terminal 132. The gate electrode G1 of the first semiconductor chip Tr1 is electrically connected to the external connection terminal 131. The source electrode S1 of the first semiconductor chip Tr1, the anode electrode An1 of the first reflux diode SBD1, the drain electrode D2 of the second semiconductor chip Tr2, and the cathode electrode Ca2 of the second reflux diode SBD2 are electrically connected to the external connection terminal 143. The gate electrode G2 of the second semiconductor chip Tr2 is electrically connected to the external connection terminal 141. The source electrode S2 of the second semiconductor chip Tr2, the anode electrode An2 of the second reflux diode SBD2, and the electrode CE2 of the capacitor C are electrically connected to the external connection terminal 142.

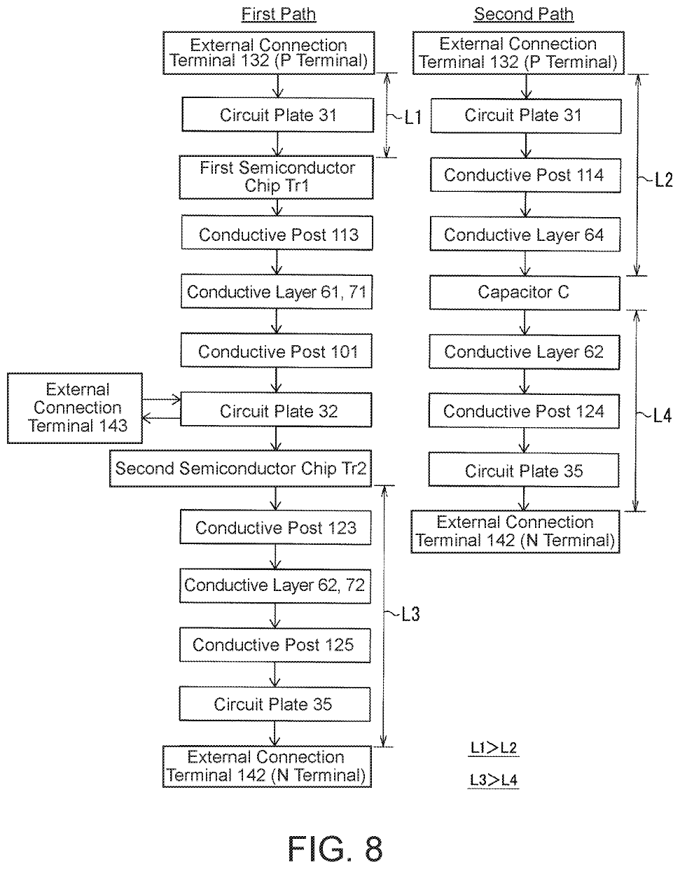

FIG. 8 is a view of current paths of the semiconductor device according to Embodiment 1 of the present invention. As shown in FIG. 8, the current paths of the semiconductor device 1 include a first path going through the first semiconductor chip Tr1 and the second semiconductor chip Tr2, and a second path going through the capacitor C.

In the first path, current flows in the order of external connection terminal 132 (P terminal)→circuit plate 31→first semiconductor chip Tr1→conductive post 113→conductive layers 61, 71→conductive post 101→circuit plate 32→external connection terminal 143, and external connection terminal 143→second semiconductor chip Tr2→conductive post 123→conductive layers 62, 72→conductive post 125→circuit plate 35→external connection terminal 142 (N terminal).

In the second path, following the charge/discharge of the capacitor C, current flows in the order of external connection terminal 132 (P terminal)→circuit plate 31→conductive post 114→conductive layer 64→capacitor C→conductive layers 62, 72→conductive post 124→circuit plate 35→external connection terminal 142 (N terminal).

In the semiconductor device 1, the length of the current path from the external connection terminal 132 (P terminal) to the electrode CE1 of the capacitor C is shorter than the length of the current path from the external connection terminal 132 (P terminal) to the drain electrode D1 of the first semiconductor chip Tr1. For example, as shown in FIGS. 3, 6, and 8, a length L2 of the current path from the external connection terminal 132 (P terminal) to the electrode CE1 of the capacitor C via the conductive post 114 and the conductive layer 64 is shorter than a length L1 of the current path from the external connection terminal 132 (P terminal) to the drain electrode D1 of the first semiconductor chip Tr1 via the circuit plate 31. As shown in FIGS. 3 and 6, the respective “length of the current path” between two elements is defined as the shortest current path length (i.e., a sum of the shortest current path lengths successively connecting intermediate nodes, if any) connecting the two elements. In FIG. 6, the dimensions in the Z-axis direction are exaggerated as compared with the dimensions in the X-axis and Y-axis directions. In actuality, the length of the current path along the conductive post 114 contributes only a small amount to the length L2 of the current path from the external connection terminal 132 (P terminal) to the electrode CE1 of the capacitor C. Therefore, as shown in FIG. 3, it usually is sufficient if L2 is shorter than L1 in a plan view (i.e., in terms of the lengths in the X-Y plane).

Furthermore, the length of the current path from the electrode CE2 of the capacitor C to the external connection terminal 142 (N terminal) is shorter than the length of the current path from the source electrode S2 of the second semiconductor chip Tr2 to the external connection terminal 142 (N terminal). For example, as shown in FIG. 8, a length L4 of the current path from the electrode CE2 of the capacitor C to the external connection terminal 142 (N terminal) via the conductive layer 62 (or the conductive layer 72), the conductive post 124, and the circuit plate 35 is shorter than a length L3 of the current path from the source electrode S2 of the second semiconductor chip Tr2 to the external connection terminal 142 via the conductive post 123, the conductive layer 62 (or the conductive layer 72), the conductive post 125, and the circuit plate 35. As shown in FIGS. 3 and 6, the respective “length of the current path” between two elements is defined as the shortest current path length (i.e., a sum of the shortest current path lengths successively connecting intermediate nodes, if any) connecting the two elements. As described above, in FIG. 6, the dimensions in the Z-axis direction are exaggerated as compared with the dimensions in the X-axis and Y-axis directions. In actuality, the lengths of the current paths along the conductive posts 123, 125 contribute only a small amount to the length L3 of the current path from the source electrode S2 of the second semiconductor chip Tr2 to the external connection terminal 142. Also, the length of the current path along the conductive post 124 contributes only a small amount to the length L4 of the current path from the electrode CE2 of the capacitor C to the external connection terminal 142 Therefore, as shown in FIG. 3, it usually is sufficient if L4 is shorter than L3 in a plan view (i.e., in terms of the lengths in the X-Y plane).

As described above, the semiconductor device 1 according to an embodiment of the present invention includes: a circuit substrate (the insulating circuit substrate 10, for example); the printed substrate 50 disposed so as to face the insulating circuit substrate 10; switching elements (the first semiconductor chip Tr1 and the second semiconductor chip Tr2, for example) attached to the insulating circuit substrate 10 and collectively having a positive potential-side first electrode (the drain electrode D1, for example) and a negative potential-side second electrode (the source electrode S2, for example); a circuit impedance reduction element (the capacitor C, for example) attached to the printed substrate 50; a first conductive post (the conductive post 114, for example) electrically and mechanically connected to the insulating circuit substrate 10 and the printed substrate 50; a second conductive post (the conductive post 124, for example) disposed in a position separated from the conductive post 114 and electrically and mechanically connected to the insulating circuit substrate 10 and the printed substrate 50; a first external connection terminal (the external connection terminal 132, for example) going through the printed substrate 50 and mechanically connected to the insulating circuit substrate 10, and electrically connected to the drain electrode D1; and a second external connection terminal (the external connection terminal 142, for example) going through the printed substrate 50 and mechanically connected to the insulating circuit substrate 10, and electrically connected to the source electrode S2.

The capacitor C includes a third electrode (the electrode CE1, for example) electrically connected via the conductive post 114 to the external connection terminal 132, and a fourth electrode (the electrode CE2, for example) electrically connected via the conductive post 124 to the external connection terminal 142. The length L2 of the current path between the external connection terminal 132 and the electrode CE1 is shorter than the length L1 of the current path between the external connection terminal 132 and the drain electrode D1. The length L4 of the current path between the external connection terminal 142 and the electrode CE2 is shorter than the length L3 of the current path between the external connection terminal 142 and the drain electrode S2.

This connects the capacitor C in parallel to the switching elements. Due to this, even in a case where the switching elements turn ON or turn OFF and the voltage oscillates between the first electrode and the second electrode, it is possible to suppress the oscillation (fluctuation) of the voltage via the charging or discharging of the capacitor, and thus possible to reduce surge voltage (large wave voltage). In addition, L1>L3, and L2>L4. This keeps the inductance of the current path between the external connection terminals 132, 142 and the capacitor C at a low level, and increases charge/discharge responsiveness of the capacitor C. Due to this, the semiconductor device 1 can further increase the voltage oscillation suppression effects in the current path (between the external connection terminals 132 and 142, for example) of the switching elements and the surge voltage reduction effects.

In addition, the semiconductor device 1 includes a third conductive post (the conductive post 123, for example) electrically and mechanically connected to the source electrode S2 and the printed substrate 50. The electrode CE2 is electrically connected to the conductive post 123. This connects the capacitor C in parallel to the switching elements via the conductive posts 114, 123.

The insulating circuit substrate 10 includes a first circuit plate (the circuit plate 31, for example) and a second circuit plate (the circuit plate 35) provided in a position separated from the circuit plate 31. The external connection terminal 132 and the conductive post 114 are electrically connected via the circuit plate 31. The conductive post 124 and the external connection terminal 142 are electrically connected via the circuit plate 35. Due to this, current flows between the external connection terminal 132 and the capacitor C via the circuit plate 31 and the conductive post 114. Current also flows between the capacitor C and the external connection terminal 142 via the conductive post 124 and the circuit plate 35.

The printed substrate 50 includes a first conductive layer (the conductive layer 64, for example) electrically and mechanically connected to the conductive post 114, and a second conductive layer (the conductive layers 62, 72, for example) provided in a position separated from the conductive layer 64 and electrically and mechanically connected to the conductive post 124. The electrode CE1 is electrically and mechanically connected to the conductive layer 64. The electrode CE2 is electrically and mechanically connected to the conductive layers 62, 72. Due to this, current flows between the external connection terminal 132 and the capacitor C via the circuit plate 31, the conductive post 114, and the conductive layer 64. Current also flows between the capacitor C and the external connection terminal 142 via the conductive layers 62, 72, the conductive post 124, and the circuit plate 32.

The semiconductor device 1 also includes the insulating resin 80. The insulating resin 80 covers and seals at least a portion of the insulating circuit substrate 10, and covers and seals the switching elements, the printed substrate 50, the capacitor C, and the conductive posts 101, 111 to 114, 116, 121 to 126. The external connection terminals 131, 132, 141 to 143 protrude from the insulating resin 80. Thus, the insulating resin 80 seals the inside of the semiconductor device 1. Furthermore, the insulating resin 80 integrates the components forming the semiconductor device 1 (for example, the insulating circuit substrate 10, the switching elements, the printed substrate 50, the capacitor C, the conductive posts 101, 111 to 114, 116, 121 to 126, and the external connection terminals 131, 132, 141 to 143).

The switching elements include a first switching element (the first semiconductor chip Tr1, for example) and a second switching element (the second semiconductor chip Tr2) connected in series to the first semiconductor chip Tr1. The first semiconductor chip Tr1 includes a first source electrode (the source electrode S1, for example) and a first gate electrode (the gate electrode G1, for example) on the front surface, and includes a first rear surface electrode (the drain electrode D1, for example) on the rear surface. The second semiconductor chip Tr2 includes a second source electrode (the source electrode S2, for example) and a second gate electrode (the gate electrode G2, for example) on the front surface, and includes a second rear surface electrode (the drain electrode D2, for example) on the rear surface. The source electrode S1 and the drain electrode D2 are electrically connected. The drain electrode D1 is the first electrode, and the source electrode S2 is the second electrode. This makes it possible to realize a 2-in-1 module in which the upper and lower arms are packed in a single package as the semiconductor device 1.

The capacitor C is disposed in the vicinity of an outer edge part 50L (see FIG. 1) of the printed substrate 50. Due to this, it is possible for the capacitor C and the first semiconductor chip Tr1 or the second semiconductor chip Tr2 to not overlap in the thickness direction of the semiconductor device 1. The first semiconductor chip Tr1 and the second semiconductor chip Tr2 tend to generate heat due to the flowing of current, and the capacitor C tends to have a change in capacitance when temperature increases. However, in the semiconductor device 1, the capacitor C is disposed in the vicinity of the outer edge part 50L of the printed substrate 50, and thus disposed so as to be away from the first semiconductor chip Tr1 and the second semiconductor chip Tr2, which are heat generating sources. This makes it possible for the capacitor C to suppress a change in capacitance.

The external connection terminals 132, 142, 143 used as the P terminal, N terminal, and output terminal of the semiconductor device 1 also tend to generate heat due to the flowing of current and act as heat generating sources. Due to this, the capacitor C is also preferably disposed so as to be separated from the external connection terminals 132, 142.

In the printed substrate 50, the conductive post 114 is disposed between the capacitor C and the external connection terminal 132. This makes it possible for the conductive post 114 to suppress a bonding material from flowing to the external connection terminal 132 side on the occasion of using the conductive bonding material to electrically and mechanically bond the electrode CE1 of the capacitor C and the conductive layer 64. Thus, it is possible to prevent the capacitor C and the external connection terminal 132 from being bonded by the bonding material.

Similarly, in the printed substrate 50, the conductive post 124 is disposed between the capacitor C and the external connection terminal 142. This makes it possible for the conductive post 124 to suppress a bonding material from flowing to the external connection terminal 142 side on the occasion of using the conductive bonding material to electrically and mechanically bond the electrode CE2 of the capacitor C and the conductive layer 62. Thus, it is possible to prevent the capacitor C and the external connection terminal 142 from being bonded by the bonding material.

### Embodiment 2

In Embodiment 1, the circuit impedance reduction element was described as being made of the capacitor C. However, the embodiments of the present invention are not limited to this. The circuit impedance reduction element may include a resistor element.

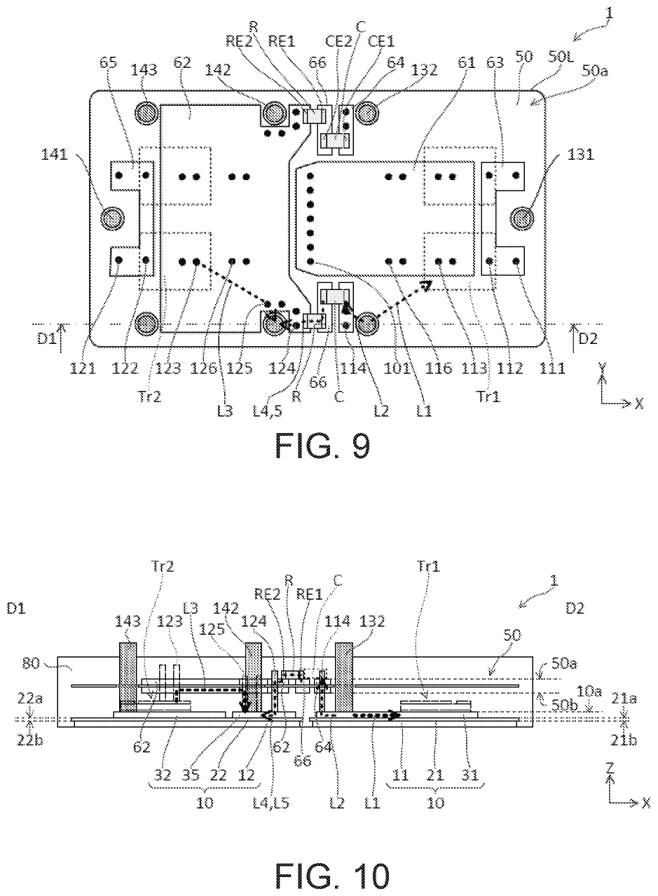

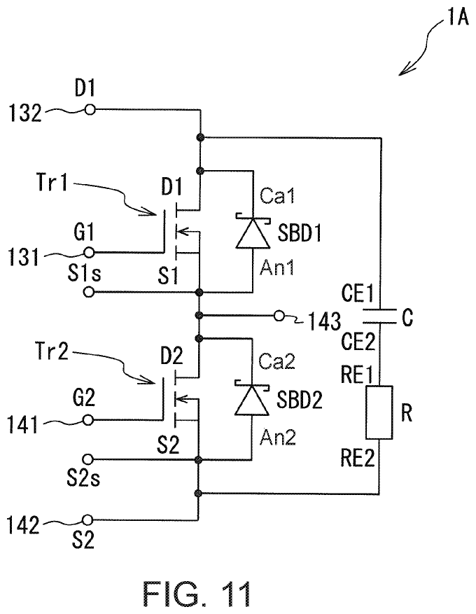

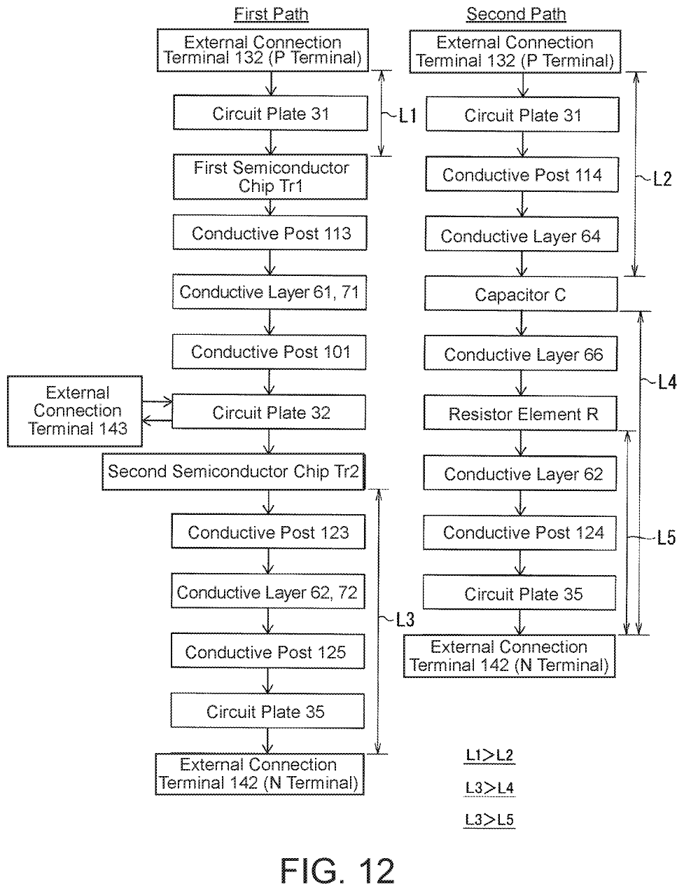

FIG. 9 is a view of a configuration example of the semiconductor device according to Embodiment 2 of the present invention. FIG. 10 is a cross-sectional view of a configuration example of the semiconductor device according to Embodiment 2 of the present invention. FIG. 11 is a circuit diagram of an equivalent circuit of the semiconductor device according to Embodiment 2 of the present invention. FIG. 12 is a view of current paths of the semiconductor device according to Embodiment 2 of the present invention. Specifically, FIG. 9 is a plan view of a configuration example of a front surface 50a side of a printed substrate 50A of a semiconductor device 1A according to Embodiment 2. FIG. 10 is a cross-sectional view in which the semiconductor device 1A has been cut along the D1-D2 line shown in FIG. 9. The insulating circuit substrate according to Embodiment 2 has the same configuration as the insulating circuit substrate 10 described in Embodiment 1 and thus is not shown in the drawing.

As shown in FIG. 9 and FIG. 10, the semiconductor device 1A includes the printed substrate 50A. The printed substrate 50A has a conductive layer 66 provided on the front surface 50a side. Furthermore, as shown in FIG. 11, the semiconductor device 1A includes, as circuit impedance reduction elements, a capacitor C and a resistor element R connected in series to the capacitor. One electrode CE1 of the capacitor C is electrically and mechanically connected via a conductive bonding material to a conductive layer 64. The other electrode CE2 of the capacitor C is electrically and mechanically connected via a conductive bonding material to the conductive layer 66. One electrode RE1 of the resistor element R is electrically and mechanically connected via a conductive bonding material to the conductive layer 66. The other electrode RE2 of the resistor element R is electrically and mechanically connected via a conductive bonding material to a conductive layer 62.

Due to this, as shown in FIG. 12, in the semiconductor device 1A, following the charge/discharge of the capacitor C, current flows in the order of external connection terminal 132 (P terminal)→circuit plate 31→conductive post 114→conductive layer 64→capacitor C→conductive layer 66→resistor element R→conductive layers 62, 72→conductive post 124→circuit plate 35→external connection terminal 142 (N terminal). As shown in FIGS. 9, 10, and 12, in the semiconductor device 1A as well, a length L4 of the current path between the external connection terminal 142 and the electrode CE2 is shorter than a length L3 of the current path between the external connection terminal 142 and the source electrode S2. In addition, a length L5 of the current path between the external connection terminal 142 and the resistor element R is preferably shorter than the length L3. As shown in FIGS. 9 and 10, the respective “length of the current path” between two elements is defined as the shortest current path length (i.e., a sum of the shortest current path lengths successively connecting intermediate nodes, if any) connecting the two elements. In FIG. 10, the dimensions in the Z-axis direction are exaggerated as compared with the dimensions in the X-axis and Y-axis directions. In actuality, the lengths of the current paths along the conductive posts 114, 123, 124, and 125 are much smaller than those depicted. Accordingly, as shown in FIG. 9, it usually is sufficient if L2 is shorter than L1 and L4 is shorter than L3 in a plan view (i.e., in terms of the lengths in the X-Y plane). Moreover, it is preferable that L5 is shorter than L3 in the plan view. In the semiconductor device 1A, due to the circuit impedance reduction elements including a resistor element R, it is possible to further suppress voltage oscillation in the current path (between the external connection terminals 132 and 142, for example) of the switching elements.

### Embodiment 3

In Embodiment 1, the capacitor C was described as being disposed on the front surface 50a side of the printed substrate 50. However, the embodiments of the present invention are not limited to this. In an embodiment of the present invention, the capacitor C may be disposed so as to fit into a through-hole provided in the printed substrate.

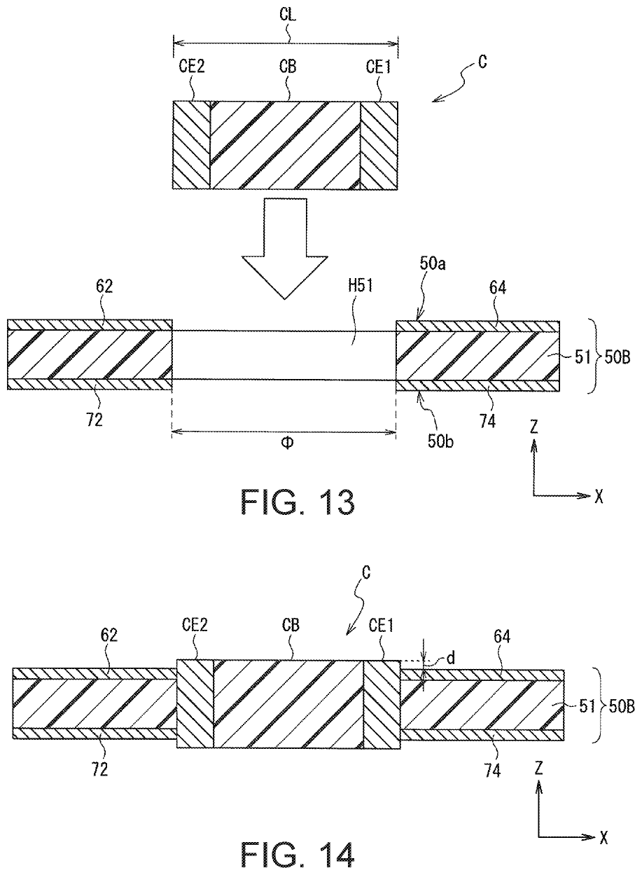

FIG. 13 and FIG. 14 are cross-sectional views of configuration examples of the printed substrate according to Embodiment 3 of the present invention. As shown in FIG. 13, a printed substrate 50B according to Embodiment 3 is provided with a through-hole H51 for fitting a capacitor C. As described above, the capacitor C is a ceramic capacitor, for example, and includes a ceramic capacitor body CB and electrodes CE1, CE2 positioned on both ends of the body. The diameter φ of the through-hole H51 is slightly larger than the complete length CL of the capacitor C (the distance from the tip of the electrode CE1 to the tip of the electrode CE2). This makes it possible to fit the capacitor into the through-hole H51 as shown by the arrow in FIG. 13. As shown in FIG. 14, the capacitor C is disposed inside the through-hole H51 in the printed substrate 50B, which makes it possible to reduce a step d between the printed substrate 50B and the capacitor C. Due to this, on the occasion of forming the insulating resin 80, it is possible to increase the fluidity of a molten resin (the insulating resin 80 in a molten state), and to prevent a gap from occurring near the step between the printed substrate 50B and the capacitor C.

In Embodiment 3 as well, the capacitor C and the printed substrate 50B may be electrically and mechanically connected via a conductive bonding material. This makes it possible to increase the bonding strength and electrical connection reliability between the capacitor C and the printed substrate 50B.

Furthermore, as shown in FIG. 14, the printed substrate 50B may be have conductive layers 72, 74 on the rear surface side. The conductive layer 72 has the same shape and the same size as the conductive layer 62, for example. In a plan view seeing through the base member 51, the conductive layer 72 is disposed in a position overlapping the conductive layer 62. Similarly, the conductive layer 74 has the same shape and the same size as the conductive layer 64, for example. In a plan view seeing through the base member 51, the conductive layer 74 is disposed in a position overlapping the conductive layer 64. The capacitor C is respectively connected to the conductive layers 72, 74 by being fitted into the through-hole H51. This increases the locations where the capacitor C and the printed substrate 50B are electrically connected as compared to a substrate without the conductive layers 72, 74. Thus, it is possible to increase the electrical connection reliability between the capacitor C and the printed substrate 50B.

### Other Embodiments

The present invention was described using the embodiments and modification examples above, but the descriptions and drawings forming a part of the disclosure should not be construed as limiting the present invention. Various substitute embodiments, examples, and applied techniques should be clear to a person skilled in the art based on this disclosure.

For example, in the embodiments above, the first semiconductor chip Tr1 and the second semiconductor chip Tr2 were described as being SiC-MOSFETs. However, in the embodiments of the present invention, the first semiconductor chip Tr1 and the second semiconductor chip Tr2 are not limited to being SiC-MOSFETs. At least one of the first semiconductor chip Tr1 and the second semiconductor chip Tr2 may be an IGBT, for example. In the case of an IGBT, the drain may instead be read as the collector, and the source may instead be read as the emitter.

In addition, the gate insulating film of the first semiconductor chip Tr1 and the second semiconductor chip Tr2 is not limited to being a silicon oxide film (SiO₂ film) and may be a different insulating film. For the gate insulating film, it is also possible to use a silicon oxynitride (SiON) film, a strontium oxide (SrO) film, a silicon nitride (Si₃N₄) film, or an aluminum oxide (Al₂O₃) film. A single-layer insulating film or a composite film with several layers or the like can also be used for the gate insulating film. A MOSFET that uses an insulating film other than a SiO₂ film as the gate insulating film may be called a MIS (metal-insulator-semiconductor) FET. A MISFET means a more comprehensive insulated gate transistor, including a MOS transistor.

It will be apparent to those skilled in the art that various modifications and variations can be made in the present invention without departing from the spirit or scope of the invention. Thus, it is intended that the present invention cover modifications and variations that come within the scope of the appended claims and their equivalents. In particular, it is explicitly contemplated that any part or whole of any two or more of the embodiments and their modifications described above can be combined and regarded within the scope of the present invention.

What is claimed is:

1. A semiconductor device, comprising:
a circuit substrate;
a printed substrate disposed above the circuit substrate so as to face the circuit substrate;
switching elements attached to the circuit substrate, collectively having a first electrode as a positive-side electrode and a second electrode as a negative-side electrode;
a circuit impedance reduction element attached to the printed substrate;
a first conductive post electrically and mechanically connected to the circuit substrate and the printed substrate;
a second conductive post disposed in a position separated from the first conductive post and electrically and mechanically connected to the circuit substrate and the printed substrate;
a first external connection terminal going through the printed substrate and mechanically connected to the circuit substrate, and electrically connected to the first electrode; and
a second external connection terminal going through the printed substrate and mechanically connected to the circuit substrate, and electrically connected to the second electrode,
wherein the circuit impedance reduction element includes:
a third electrode electrically connected to the first external connection terminal via the first conductive post; and
a fourth electrode electrically connected to the second external connection terminal via the second conductive post,
wherein a length of a current path between the first external connection terminal and the third electrode is shorter than a length of a current path between the first external connection terminal and the first electrode, and
wherein a length of a current path between the second external connection terminal and the fourth electrode is shorter than a length of a current path between the second external connection terminal and the second electrode.

2. The semiconductor device according to claim 1, further comprising:
a third conductive post electrically and mechanically connected to the second electrode and the printed substrate,
wherein the fourth electrode is electrically connected to the third conductive post.

3. The semiconductor device according to claim 1, wherein the circuit substrate includes:
a first circuit plate; and
a second circuit plate provided in a position separated, in a plan view, from the first circuit plate,
wherein the first external connection terminal and the first conductive post are electrically connected via the first circuit plate, and
wherein the second conductive post and the second external connection terminal are electrically connected via the second circuit plate.

4. The semiconductor device according to claim 1, wherein the printed substrate comprises:
a first conductive layer electrically and mechanically connected to the first conductive post; and
a second conductive layer provided in a position separated, in a plan view, from the first conductive layer and electrically and mechanically connected to the second conductive post,
wherein the third electrode is electrically and mechanically connected to the first conductive layer, and
wherein the fourth electrode is electrically and mechanically connected to the second conductive layer.

5. The semiconductor device according to claim 1, further comprising:
an insulating resin covering and sealing at least a portion of the circuit substrate, and covering and sealing the switching elements, the printed substrate, the circuit impedance reduction element, the first conductive post, and the second conductive post,
wherein the first external connection terminal and the second external connection terminal protrude from the insulating resin.

6. The semiconductor device according to claim 1, wherein the switching elements includes:
a first switching element; and
a second switching element connected in series to the first switching element.

7. The semiconductor device according to claim 6,
wherein the first switching element includes a source electrode and a gate electrode on a front surface, and includes a drain electrode on a rear surface,
wherein the second switching element includes a source electrode and a gate electrode on a front surface, and includes a drain electrode on a rear surface,
wherein the source electrode of the first switching element and the drain electrode of the second switching element are electrically connected to each other, and
wherein the drain electrode of the first switching element is the first electrode, and the source electrode of the second switching element is the second electrode.

8. The semiconductor device according to claim 1, wherein the circuit impedance reduction element includes a capacitor.

9. The semiconductor device according to claim 8, wherein the circuit impedance reduction element further includes a resistor element connected in series to the capacitor.

10. The semiconductor device according to claim 1, wherein the circuit impedance reduction element is disposed in a vicinity of an outer edge part of the printed substrate.

11. The semiconductor device according to claim 1,
wherein a through-hole to accommodate the circuit impedance reduction element is provided in the printed substrate, and
wherein the circuit impedance reduction element is fitted in the through-hole.

12. The semiconductor device according to claim 1, wherein the first conductive post is disposed in the printed substrate, in a plan view, between the circuit impedance reduction element and the first external connection terminal.

13. The semiconductor device according to claim 1, wherein the second conductive post is disposed, in a plan view, between the circuit impedance reduction element and the second external connection terminal.

14. The semiconductor device according to claim 12, wherein the second conductive post is disposed, in a plan view, between the circuit impedance reduction element and the second external connection terminal.

15. The semiconductor device according to claim 1,
wherein in a plan view, a pair of the first external connection terminal and the second external connection terminal is disposed adjacent to and along an elongated side of the circuit substrate, and in the plan view, the circuit impedance reduction element is disposed between the pair of the first external connection element and the second external connection element, and
wherein another pair of the first external connection terminal and the second external connection terminal is provided adjacent to and along another elongated side of the circuit substrate that is opposite to said elongated side in the plan view, and another circuit impedance reduction element is provided between said another pair of the first external connection element and the second external connection element so that said pair of the first and second external connection terminals with said circuit impedance reduction element and said another pair of the first and second external connection terminals with said another circuit impedance reduction element are arranged in a symmetrical manner with respect to a center line of the circuit substrate that is parallel to said elongated side and said another elongated side of the circuit substrate.
